(19) United States
(12) Patent Application Publication
(10) Pub. No.: US 2025/0118601 A1
(43) Pub. Date: Apr. 10, 2025

(54) METHOD AND APPARATUS FOR DIVIDING WAFER

(71) Applicant: DISCO CORPORATION, Tokyo (JP)

(72) Inventor: Shinya ARUGA, Tokyo (JP)

(21) Appl. No.: 18/910,669

(22) Filed: Oct. 9, 2024

(30) Foreign Application Priority Data
Oct. 10, 2023 (JP) 2023-175105

(51) Int. Cl. H01L 21/78; H01L 21/304; H01L 21/67; H01L 21/683

(52) U.S. Cl. CPC H01L 21/78; H01L 21/304; H01L 21/67092; H01L 21/6836; H01L 2221/68327

(57) ABSTRACT

A method of dividing a wafer along division initiating points formed in the wafer along a grid of streets established on a face side of the wafer includes a holding step of holding a ring frame that supports the wafer through a sheet affixed to the ring frame and a reverse side, opposite the face side, of the wafer, on a ring-shaped holding table, a gripping step of gripping the wafer between a lower bar that abuts against a lower surface of the sheet along the streets on the wafer and an upper bar that abuts against an upper surface of the wafer along the streets thereon, and a dividing step of severing the wafer along the division initiating points by pressing a presser bar extending parallel to the upper bar against the upper surface of the wafer along the streets while the presser bar is being ultrasonically vibrated.

### BACKGROUND OF THE INVENTION

### Field of the Invention

The present invention relates to a method of and an apparatus for dividing a wafer along a grid of streets established thereon.

### Description of the Related Art

According to a known process of manufacturing semiconductor devices, for example, the face side of a circular semiconductor wafer (hereinafter simply referred to as a “wafer”) has a plurality of device areas demarcated by a grid of streets also referred to as projected dicing lines established thereon, and devices such as integrated circuits (ICs) or large-scale integration (LSI) circuits are constructed in the respective device areas. The wafer with the devices thus constructed on the face side is then divided along the streets into a plurality of chips.

Japanese Patent Laid-open No. 2019-140266 discloses a method of dividing a wafer along streets established thereon. According to the disclosed method, a tape is affixed to a wafer including modified layers that have been formed therein by application of a laser beam to the wafer, and then expanded to divide the wafer along the modified layers that function as division initiating points.

However, the above proposed method of dividing the wafer by expanding the tape affixed thereto is not effective on wafers made of a hard material such as silicon carbide (Sic) or sapphire, for example. One solution disclosed in Japanese Patent Laid-open Nos. 2023-100580, 2013-058671, and 2016-207921 uses a breaking apparatus including a severance blade that is pressed against a wafer to sever the wafer along streets established thereon.

### SUMMARY OF THE INVENTION

In recent years, opportunities have arisen to sever wafers with a metal film of titanium, gold, or copper, for example, formed on their reverse side. Attempts to use the breaking apparatus to sever those wafers backed with the metal film have failed to achieve desired severance because the severance blade is normally unable to cut through the metal film, but ends up bending the metal film. The severance blade may be pushed under stronger forces into the wafers backed with the metal film to sever the wafers. However, the stronger forces that are applied to the wafers tend to bring the chips into contact with each other, possibly chipping the chips. When the breaking apparatus is used to sever thicker wafers, since stronger forces need to be applied to the wafers, the wafers may not be severed neatly, or undue time is required to sever the wafers.

It is therefore an object of the present invention to provide a method of and an apparatus for dividing a wafer efficiently in a short period of time.

In accordance with an aspect of the present invention, there is provided a method of dividing a wafer along division initiating points formed in the wafer along a grid of streets established on a face side of the wafer, the method including a holding step of holding a ring frame that supports the wafer through a sheet affixed to the ring frame and a reverse side, opposite the face side, of the wafer, on a ring-shaped holding table, a gripping step of gripping the wafer between a lower bar that abuts against a lower surface of the sheet along the streets on the wafer and an upper bar that abuts against an upper surface of the wafer along the streets thereon, and a dividing step of severing the wafer along the division initiating points by pressing a presser bar extending parallel to the upper bar against the upper surface of the wafer at a position spaced from the upper bar while the presser bar is being ultrasonically vibrated.

In accordance with another aspect of the present invention, there is provided a method of dividing a wafer along division initiating points formed in the wafer along a grid of streets established on a face side of the wafer, the method including a holding step of holding a ring frame that supports the wafer through a sheet affixed to the ring frame and a reverse side, opposite the face side, of the wafer, on a ring-shaped holding table, and a dividing step of severing the wafer along the division initiating points by pressing a presser bar downwardly against an upper surface of the wafer along the streets with the sheet having a lower surface supported on a support while the presser bar is being ultrasonically vibrated.

In accordance with a further aspect of the present invention, there is provided an apparatus for dividing a wafer along division initiating points formed in the wafer along a grid of streets established on a face side of the wafer, the apparatus including a ring-shaped holding table for holding thereon a ring frame of a frame unit that includes the ring frame, the wafer, and a sheet affixed to the ring frame and the wafer, thereby supporting the wafer on the ring frame through the sheet, a lower bar disposed within the holding table for linearly abutting against the sheet of the frame unit held on the holding table, a lower bar raising and lowering mechanism for raising and lowering the lower bar, an upper bar disposed in confronting relation to the lower bar for linearly abutting against an upper surface of the wafer of the frame unit held on the holding table, an upper bar raising and lowering mechanism for raising and lowering the upper bar, a presser bar disposed parallel to the upper bar for pressing the wafer of the frame unit held on the holding table, and an ultrasonic vibrator attached to the presser bar for ultrasonically vibrating the presser bar.

In accordance with a still further aspect of the present invention, there is provided an apparatus for dividing a wafer along division initiating points formed in the wafer along a grid of streets established on a face side of the wafer, the apparatus including a ring-shaped holding table for holding thereon a ring frame of a frame unit that includes the ring frame, the wafer, and a sheet affixed to the ring frame and the wafer, thereby supporting the wafer on the ring frame through the sheet, a support disposed within the holding table for supporting a lower surface of the sheet of the frame unit held on the holding table, a presser bar for pressing the wafer downwardly along the streets, and an ultrasonic vibrator attached to the presser bar for ultrasonically vibrating the presser bar.

With the wafer dividing method according to the aspect of the present invention, while the wafer is being gripped along the streets between the upper bar and the lower bar, the presser bar being ultrasonically vibrated is pressed against the upper surface of the wafer at a position spaced from the upper bar. Therefore, the wafer is reliably severed along the division initiating points due to brittle fracture caused by the vibrational energy propagated from the presser bar. Even if the wafer is backed with a metal film on its reverse side or is thicker, the wafer can reliably be divided along the division initiating points within a short period of time without the need for strong forces that would otherwise be applied to the wafer and without damage caused to the chips produced from the wafer.

With the wafer dividing method according to the other aspect of the present invention, while the lower surface of the wafer is being supported on the support with the sheet interposed therebetween, the presser bar is pressed downwardly against the upper surface of the wafer along the streets while the presser bar is being ultrasonically vibrated. Therefore, the wafer is reliably severed along the division initiating points due to brittle fracture caused by the vibrational energy propagated from the presser bar. Even if the wafer is backed with a metal film on its reverse side or the wafer is thicker, the wafer can reliably be divided along the division initiating points within a short period of time without the need for strong forces that would otherwise be applied to the wafer and without damage caused to the chips produced from the wafer.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of an apparatus for dividing a wafer according to a first invention;

FIG. 2 is a perspective view of a frame unit;

FIG. 3 is a perspective view of a lower bar mechanism of the apparatus for dividing a wafer according to the first invention;

FIG. 4 is a cross-sectional view, partly in side elevation, illustrating a holding step of a method of dividing a wafer according to a first embodiment of the first invention;

FIG. 5 is a cross-sectional view, partly in side elevation, illustrating a gripping step of the method of dividing a wafer according to the first embodiment of the first invention;

FIG. 6 is a cross-sectional view, partly in side elevation, illustrating a dividing step of the method of dividing a wafer according to the first embodiment of the first invention;

FIG. 7 is a cross-sectional view, partly in side elevation, illustrating a holding step of a method of dividing a wafer according to a second embodiment of the first invention;

FIG. 8 is a cross-sectional view, partly in side elevation, illustrating a gripping step of the method of dividing a wafer according to the second embodiment of the first invention;

FIG. 9 is a cross-sectional view, partly in side elevation, illustrating a dividing step of the method of dividing a wafer according to the second embodiment of the first invention;

FIG. 10 is a perspective view of an apparatus for dividing a wafer according to a first embodiment of a second invention;

FIG. 11 is a cross-sectional view, partly in side elevation, illustrating a holding step of a method of dividing a wafer according to the first embodiment of the second invention;

FIG. 12 is a cross-sectional view, partly in side elevation, illustrating a dividing step of the method of dividing a wafer according to the first embodiment of the second invention;

FIG. 13 is a perspective view of an apparatus for dividing a wafer according to a second embodiment of the second invention;

FIG. 14 is a cross-sectional view, partly in side elevation, illustrating a holding step of a method of dividing a wafer according to the second embodiment of the second invention; and

FIG. 15 is a cross-sectional view, partly in side elevation, illustrating a dividing step of the method of dividing a wafer according to the second embodiment of the second invention.

### DETAILED DESCRIPTION OF THE PREFERRED EMBODIMENTS

### [First Invention]

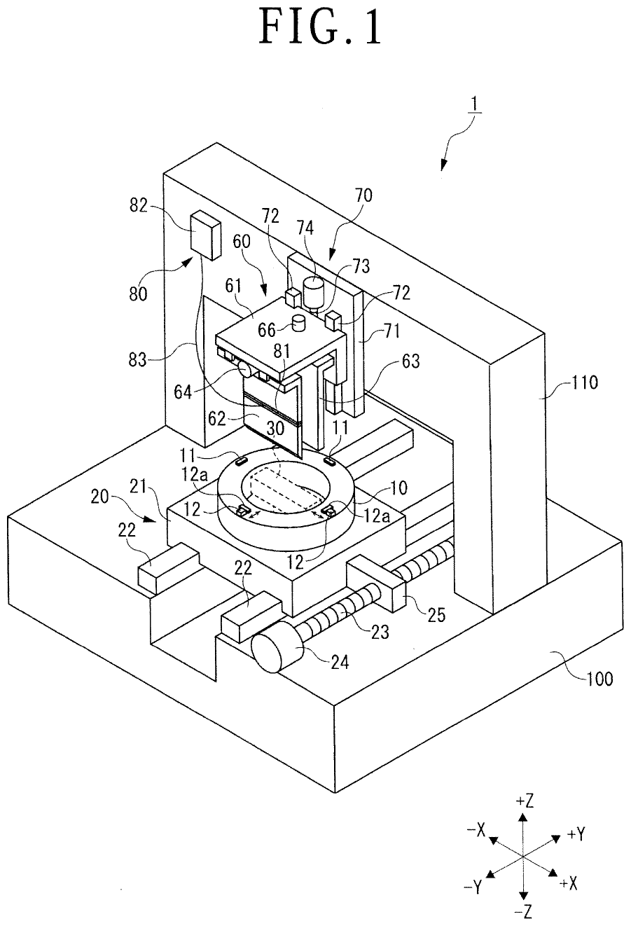

Preferred embodiments of a first invention will be described in detail below with reference to the accompanying drawings. First, structural details of an apparatus 1 (see FIG. 1) for dividing a wafer according to the first invention will be described below. The apparatus for dividing a wafer will also be referred to as a “wafer dividing apparatus.” The wafer dividing apparatus 1 will be described below with reference to FIG. 1 in reference to a three-dimensional XYZ coordinate system having an X-axis, a Y-axis, and a Z-axis. The X-axis extends horizontally leftwardly and rightwardly in a +X direction and a −X direction indicated by respective arrows, and the Y-axis extends horizontally forwardly and rearwardly in a +Y direction and a −Y direction indicated by respective arrows perpendicularly to the X-axis. The Z-axis extends vertically upwardly and downwardly in a +Z direction and a −Z direction indicated by respective arrows perpendicularly to the X-axis and the Y-axis.

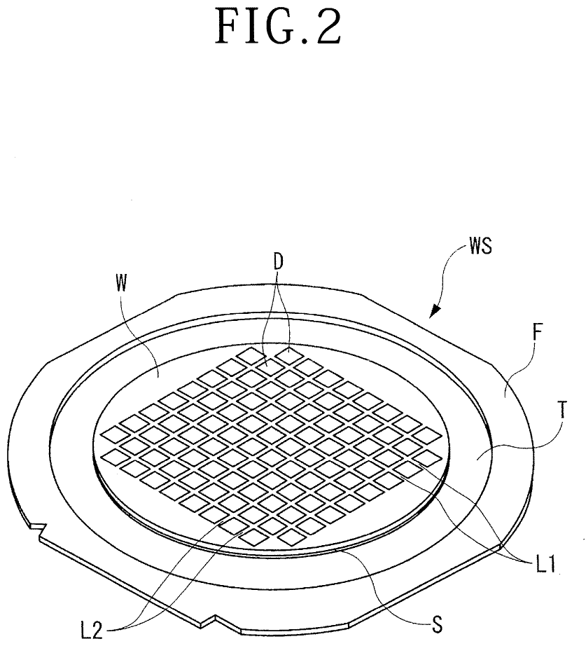

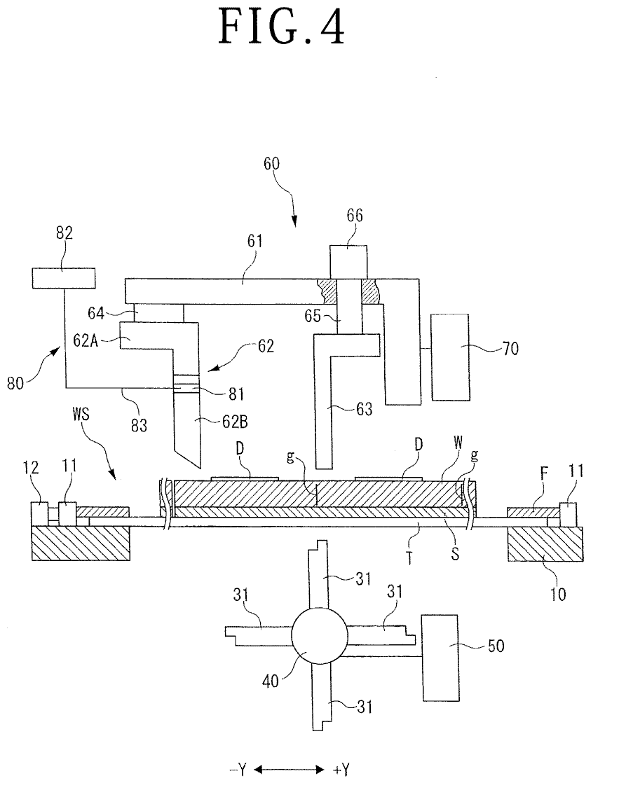

The wafer dividing apparatus 1 according to the first invention refers to an apparatus for dividing a wafer W illustrated in FIG. 2. The wafer W is a thin circular plate made of monocrystalline silicon (Si), for example, with a metal film S (see FIG. 4) of gold, silver, or copper, for example, formed on a reverse side thereof that is illustrated as a lower surface in FIG. 2. The wafer W has a plurality of rectangular areas demarcated on a face side thereof that is illustrated as an upper surface in FIG. 2, by a grid of streets or projected dicing lines L1 and L2. Devices D such as ICs or LSI circuits are constructed in the respective rectangular areas.

The wafer W with the devices D constructed on its face side is incorporated in a frame unit WS illustrated in FIG. 2. A method of dividing a wafer, also referred to as a “wafer dividing method,” according to the first invention is performed on the wafer W thus incorporated in the frame unit WS. The wafer unit WS is made up of a ring frame F made of a metal material, e.g., stainless steel, and having a circular opening, a sheet T affixed to a lower surface of the ring frame F in closing relation to the circular opening, and the wafer W whose reverse side, or more precisely, a lower surface of the metal film S, is affixed to an upper surface of the sheet T within the circular opening of the ring frame F. The wafer W is thus supported on the ring frame F by the sheet T, or stated otherwise, the wafer W, the ring frame F, and the sheet T are integrally combined with each other, making up the frame unit WS. The wafer W may be made of silicon (Si) or a harder material such as silicon carbide (SiC), glass, ceramic, or sapphire, for example.

As illustrated in FIG. 1, the wafer dividing apparatus 1 includes as major components a ring-shaped holding table 10 for holding the ring frame F of the frame unit WS thereon, a lower bar mechanism 30 disposed in the holding table 10, a presser bar mechanism 60 mounted on a portal-shaped upstanding column 110 vertically mounted on a base 100, and an ultrasonic vibration applying unit 80 also mounted on the column 110. Structural details of the holding table 10, the lower bar mechanism 30, the presser bar mechanism 60, and the ultrasonic vibration applying unit 80 will be described below.

The ring-shaped holding table 10 is rotatably mounted on a slider 21 of a horizontal moving mechanism 20. Two fixed clamps 11 and two movable clamps 12 are disposed on an upper surface of the holding table 10 at circumferentially equal angular pitches or intervals of 90°. The fixed clamps 11 are fixedly mounted on the upper surface of the holding table 10, whereas the movable clamps 12 have respective pressers 12a that are movable radially along directions indicated by arrows with respect to the holding table 10.

The holding table 10 is rotatable about its vertical central axis by a rotating mechanism, not depicted. The holding table 10 is also movable along the Y-axis by the horizontal moving mechanism 20. The horizontal moving mechanism 20 includes a pair of parallel guide rails 22 mounted on the base 100 and extending along the Y-axis, the slider 21 shaped as a rectangular plate slidably mounted on the guide rails 22 for movement therealong, a ball screw 23 disposed alongside of one of the guide rails 22, which is spaced from the other guide rail 22 in the +X direction, and extending along the Y-axis, and a servomotor 24 mounted on the base 100 as a reversible rotary actuator and coupled to an axial end of the ball screw 23. The other axial end of the ball screw 23 is rotatably supported on the base 100 by a bearing, not depicted.

A nut 25 shaped as a rectangular block is mounted on a side surface of the slider 21 which faces the ball screw 23. The nut 25 has an internally threaded hole, not depicted, operatively threaded over the ball screw 23. When the servomotor 24 is energized, the ball screw 23 is rotated about its central axis in one direction, causing the nut 25 to move the slider 21 in one direction along the Y-axis along the guide rails 22. When the servomotor 24 is reversed, the ball screw 23 is rotated about its central axis in the opposite direction, causing the nut 25 to move the slider 21 in the opposite direction along the Y-axis along the guide rails 22. Therefore, the holding table 10 mounted on the slider 21 is also movable with the slider 21 in one or the other direction along the Y-axis.

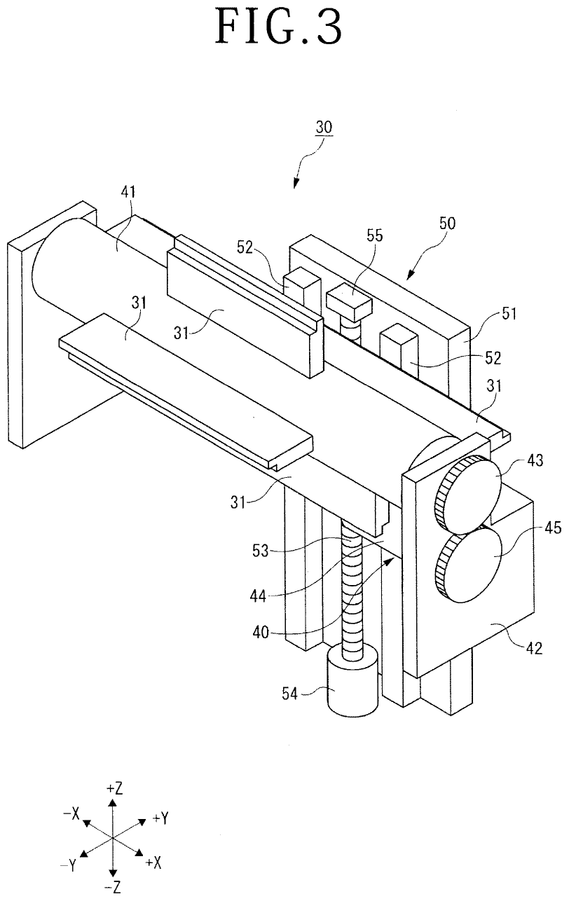

As illustrated in FIG. 3, the lower bar mechanism 30 disposed in the holding table 10 includes four lower bars 31 of different lengths disposed at circumferentially equal angular pitches or intervals of 90°, a lower bar rotating mechanism 40 for angularly moving the lower bars 31 intermittently through angles of 90°, and a lower bar raising and lowering mechanism 50 for raising and lowering the lower bars 31 along the Z-axis.

Each of the lower bars 31 is shaped as a rectangular plate that is elongate along the X-axis. The lower bars 31 are mounted radially outwardly on an outer circumferential surface of a rotor shaft 41 that extends along the X-axis and that is rotatable about its horizontal central axis. Each of the lower bars 31 has a radially outward distal end having a stepped shape. The rotor shaft 41 is rotatably supported on a frame 42 and has an axial end portion that protrudes in the +X direction through a side wall of the frame 42 and that is coupled to a driven gear 43 on one surface of the side wall of the frame 42. An electric motor 44 as a rotary actuator is mounted on the opposite surface of the side wall of the frame 42 and has an output shaft, i.e., a motor shaft, extending horizontally through the side wall of the frame 42 and coupled to a drive gear 45 on the one surface of the side wall of the frame 42. The drive gear 45 and the driven gear 43 are operatively held in mesh with each other and are equal in diameter to each other.

The rotor shaft 41, the electric motor 44, the driven gear 43, and the drive gear 45 jointly make up the lower bar rotating mechanism 40 for angularly moving the four lower bars 31 intermittently. When the electric motor 44 is energized, the rotation of its motor shaft is transmitted through the drive gear 45 and the driven gear 43 that mesh with each other to the rotor shaft 41, thereby rotating the rotor shaft 41 and the four lower bars 31 mounted thereon about the central axis of the rotor shaft 41 intermittently through angles of 90°. When the four lower bars 31 of different lengths are intermittently turned successively through 90° by the lower bar rotating mechanism 40, one at a time of the lower bars 31 whose length is commensurate with the length of the streets L1 or L2 on the wafer W held on the holding surface of the holding table 10 is positioned in a vertical orientation below the wafer W, as illustrated in FIG. 4, ready to contact the lower surface of the wafer W and grip the wafer W in coaction with an upper bar 63 to be described later.

The lower bar raising and lowering mechanism 50 for raising and lowering the frame 42 and hence the four lower bars 31 includes a pair of parallel guide rails 52 that are mounted on a base 51 shaped as a vertically upstanding rectangular plate and that extend vertically along the Z-axis, a ball screw 53 rotatably disposed between the guide rails 52 and extending vertically along the Z-axis, and a servomotor 54 mounted on the base 51 as a reversible rotary actuator and coupled to an axial end of the ball screw 53. The other axial end of the ball screw 53 is rotatably supported on the base 51 by a bearing 55. A nut, not depicted, is fixedly mounted on a rear side of the frame 42. The ball screw 53 is operatively threaded in the nut.

When the servomotor 54 is energized, the ball screw 53 is rotated about its central axis in one direction, causing the nut to move the frame 42 together with the rotor shaft 41 and the electric motor 44 in one direction along the Z-axis. When the servomotor 24 is reversed, the ball screw 53 is rotated about its central axis in the opposite direction, causing the nut to move the frame 42 together with the rotor shaft 41 and the electric motor 44 in the opposite direction along the Z-axis. Therefore, the four lower bars 31 on the rotor shaft 41 are also moved with the frame 42 in one or the other direction, i.e., raised or lowered, along the Z-axis.

Structural details of the presser bar mechanism 60 will be described below with reference to FIGS. 1 and 4. The presser bar mechanism 60 includes a slider 61 bent in a horizontal cross-sectional L-shape and supporting thereon a presser bar 62 and the upper bar 63 that hang downwardly from the slider 61. The presser bar 62 and the upper bar 63 lie parallel to each other and are spaced from each other along the Y-axis. The presser bar 62 is a plate bent in a vertical cross-sectional inverted-L-shape and includes a horizontal portion 62A and a vertical portion 62B. The horizontal portion 62A is disposed below the slider 61. The vertical portion 62B extends downwardly from an end of the horizontal portion 62A and has a lower end shaped as a sharp knife edge. A gap adjusting mechanism 64 is interposed between the horizontal portion 62A and the slider 61.

The upper bar 63 is disposed horizontally adjacent to the presser bar 62 in vertically confronting relation to the lower bars 31. The upper bar 63 extends parallel to the presser bar 62 vertically along the Z-axis and horizontally along the X-axis, i.e., along directions normal to the sheet of FIG. 4. The upper bar 63 is a plate bent in a vertical cross-sectional inverted-L-shape. A shaft 65 extends upwardly from an upper end of the upper bar 63 vertically through the slider 61. The shaft 65 has an upper end that protrudes upwardly from the slider 61 and that is joined to a damper 66. The damper 66 includes an air cylinder or a helical spring for normally biasing the upper bar 63 to move downwardly under constant forces.

The presser bar 62 and the upper bar 63 of the presser bar mechanism 60 are vertically movable by a presser bar raising and lowering mechanism 70 mounted on the column 110. As illustrated in FIG. 1, the presser bar raising and lowering mechanism 70 includes a pair of parallel guide rails 72 extending vertically along the Z-axis and mounted on a base 71 that is shaped as a vertical rectangular plate and that is fixed to the column 110, a ball screw 73 rotatably disposed between the guide rails 72 and extending vertically along the Z-axis, and a servomotor 74 mounted on the base 71 as a reversible rotary actuator and coupled to an axial upper end of the ball screw 73. The other axial lower end of the ball screw 73 is rotatably supported on the base 71 by a bearing, not depicted. The ball screw 73 is operatively threaded in a nut, not depicted, mounted on the slider 61.

When the servomotor 74 is energized, the ball screw 73 is rotated about its central axis in one direction, causing the nut to move the slider 61 in one direction along the Z-axis along the guide rails 72. When the servomotor 74 is reversed, the ball screw 73 is rotated about its central axis in the opposite direction, causing the nut to move the slider 61 in the opposite direction along the Z-axis along the guide rails 72. Therefore, the presser bar 62 and the upper bar 63 on the slider 61 are also moved together in one or the other direction, i.e., raised or lowered, along the Z-axis.

The ultrasonic vibration applying unit 80 applies ultrasonic vibrations to the presser bar 62 in a dividing step, to be described later, of the wafer dividing method. As illustrated in FIG. 1, the ultrasonic vibration applying unit 80 includes an ultrasonic vibrator 81 attached to the presser bar 62 at a vertically intermediate position on the vertical portion 62B and a high-frequency power supply 82 for supplying high-frequency electric power to the ultrasonic vibrator 81. The high-frequency power supply 82 is mounted on the column 110 and electrically connected to the ultrasonic vibrator 81 by a power cord 83 extending from the high-frequency power supply 82 to the ultrasonic vibrator 81.

### [Wafer Dividing Method]

### First Embodiment

A method of dividing a wafer, also referred to as a “wafer dividing method,” according to a first embodiment of the first invention, which is carried out by the wafer dividing apparatus 1, will be described below. The wafer dividing method refers to a method of dividing the wafer W to produce a plurality of chips therefrom by performing 1) a holding step, 2) a gripping step, and 3) a dividing step successively in the order named. 1) The holding step, 2) the gripping step, and 3) the dividing step will be described below with reference to FIGS. 4 through 6.

### 1) Holding Step:

In the holding step, as illustrated in FIG. 4, the frame unit WS is placed on the holding table 10, and the ring frame F of the frame unit WS has its outer circumferential edge held against the two fixed clamps 11. Then, the pressers 12a of the two movable clamps 12 are moved radially inwardly on the holding table 10, pressing the outer circumferential edge of the ring frame F against the two fixed clamps 11. The ring frame F and hence the frame unit WS are now held as securely positioned on the holding table 10.

The wafer W has a grid of division initiating points g formed therein by modified layers along the streets L1 and L2 (see FIG. 2). Specifically, a laser beam having a wavelength transmittable through the wafer W is applied to the wafer W along the streets L1 and L2 while keeping its focused spot within the wafer W, forming vertical modified layers partly in the wafer W along the streets L1 and L2. The modified layers thus formed act as the division initiating points g. The modified layers refer to regions whose density, refractive index, mechanical strength, and other physical properties are different from those of other regions of the wafer W.

### 2) Gripping Step:

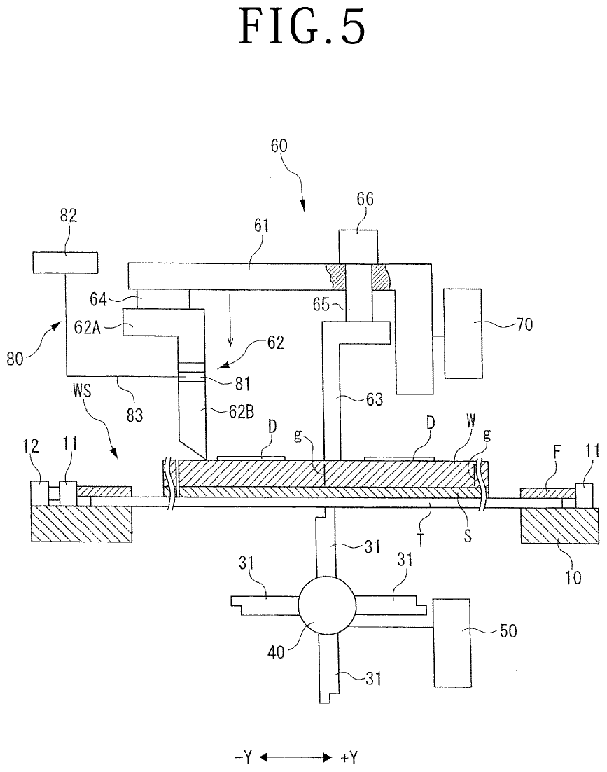

In the gripping step, as illustrated in FIG. 5, the lower bar raising and lowering mechanism 50 raises the lower bars 31 until the distal end of one of the lower bars 31 abuts against the lower surface of the wafer W with the tape T interposed therebetween in alignment with one of the streets L1, i.e., one of the division initiating points g. The presser bar raising and lowering mechanism 70 lowers the slider 61 and the presser bar 62 and the upper bar 63 that are supported on the slider 61, until the upper bar 63 has its lower surface brought into abutment against the upper surface of the wafer W in alignment with the one of the streets L1, i.e., the one of the division initiating points g and also until the knife edge of the lower end of the presser bar 62 abuts against the upper surface of the wafer W at a position offset from the one of the division initiating points g in the −Y direction. Therefore, the wafer W has its portion that is aligned with the one of the division initiating points g gripped by the upper bar 63 and the lower bar 31 that is abutting against the lower surface of the wafer W. At this time, an image capturing unit, not depicted, captures an image of the face side, i.e., the upper surface, of the wafer W, and the captured image is processed by image processing such as pattern matching to detect the positions of the streets L1 and L2.

### 3) Dividing Step:

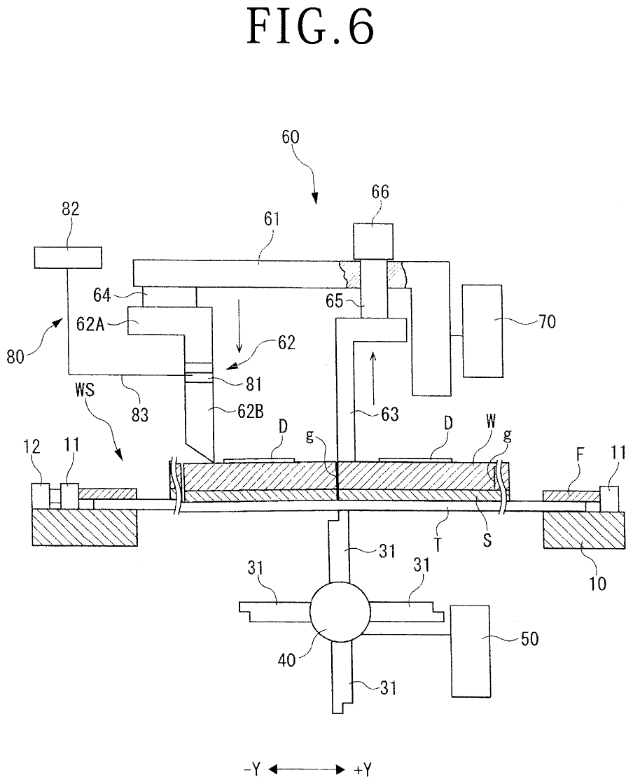

In the dividing step, as illustrated in FIG. 6, the ultrasonic vibration applying unit 80 applies ultrasonic vibrations to the presser bar 62 while the knife edge of the lower end of the presser bar 62 is pressing the upper surface of the wafer W at the position offset from the one of the division initiating points g in the −Y direction. Specifically, the high-frequency power supply 82 of the ultrasonic vibration applying unit 80 is turned on to apply the high-frequency electric power via the power cord 83 to the ultrasonic vibrator 81, actuating, i.e., exciting, the ultrasonic vibrator 81 to vibrate the presser bar 62 ultrasonically. The wafer W is now reliably severed along the one of the division initiating points g due to brittle fracture caused by the vibrational energy propagated from the presser bar 62, i.e., due to its fatigue breakdown caused by repetitive stresses.

When the severance or division of the wafer W along the one of the streets L1 is finished, the horizontal moving mechanism 20 illustrated in FIG. 1 is actuated to move the holding table 10 and the wafer W, i.e., the frame unit WS, held thereon by a pitch, i.e., the distance between two adjacent streets L1, in an indexing direction along the Y-axis. Thereafter, the holding step, the gripping step, and the dividing step are repeated on the wafer W along a next street L1. When the division of the wafer W along all of the streets L1 is finished, the rotating mechanism, not depicted, rotates the holding table 10 and the wafer W, i.e., the frame unit WS, held thereon about its vertical central axis through an angle of 90°, and the holding step, the gripping step, and the dividing step are carried out on the wafer W along one of the streets L2 that extend perpendicularly to the streets L1. When the division of the wafer W along all of the streets L2 is finished, the wafer W has been divided into a plurality of chips.

With the wafer dividing method according to the first embodiment of the first invention, even the wafer W backed with the metal film S on its reverse side can reliably be divided along the division initiating points g within a short period of time without the need for strong forces that would otherwise be applied to the wafer W and without damage caused to the chips produced from the wafer W. According to the present embodiment, furthermore, the presser bar 62 abuts against the upper surface of the wafer W at the position offset from the one of the division initiating points g in the −Y direction, and presses the upper surface of the wafer W under predetermined forces. Consequently, bending stresses are developed at the one of the division initiating points g, dividing the wafer W along the one of the division initiating points g reliably within a short period of time. Even if the wafer W is thicker, the wafer W can be divided along the division initiating points g reliably within a short period of time without the need for strong forces that would otherwise be applied to the wafer W and without causing damage to the chips produced from the wafer W.

### Second Embodiment

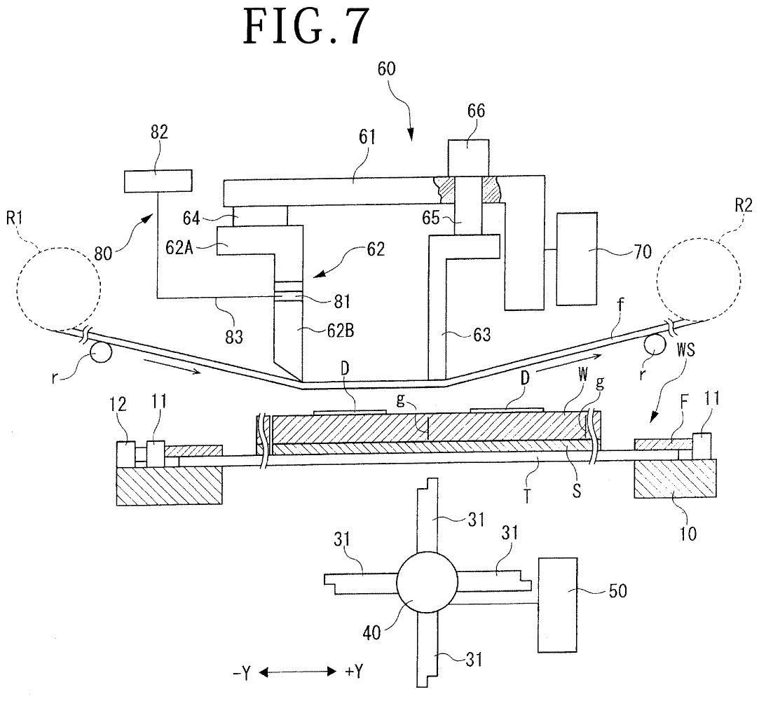

A method of dividing the wafer W according to a second embodiment of the first invention will be described below. The wafer dividing method according to the second embodiment also refers to a method of dividing the wafer W to produce a plurality of chips therefrom by performing 1) a holding step, 2) a gripping step, and 3) a dividing step successively in the order named, as is the case with the first embodiment. 1) The holding step, 2) the gripping step, and 3) the dividing step will be described below with reference to FIGS. 7 through 9.

### 1) Holding Step:

In the holding step, as illustrated in FIG. 7, the frame unit WS is placed on the holding table 10, and the ring frame F of the frame unit WS has its outer circumferential edge held against the two fixed clamps 11. Then, the pressers 12a of the two movable clamps 12 are moved radially inwardly on the holding table 10, pressing the outer circumferential edge of the ring frame F against the two fixed clamps 11. The ring frame F and hence the frame unit WS are now held as securely positioned on the holding table 10.

According to the present embodiment, a protective film f wound as a supply roll R1 is reeled out and coiled into a take-up roll R2. The length of the protective film f between the rolls R1 and R2 is kept taut above the wafer W by being pressed by two guide rollers r disposed adjacent to the respective rollers R1 and R2 and the presser bar 62 and the upper bar 63.

### 2) Gripping Step:

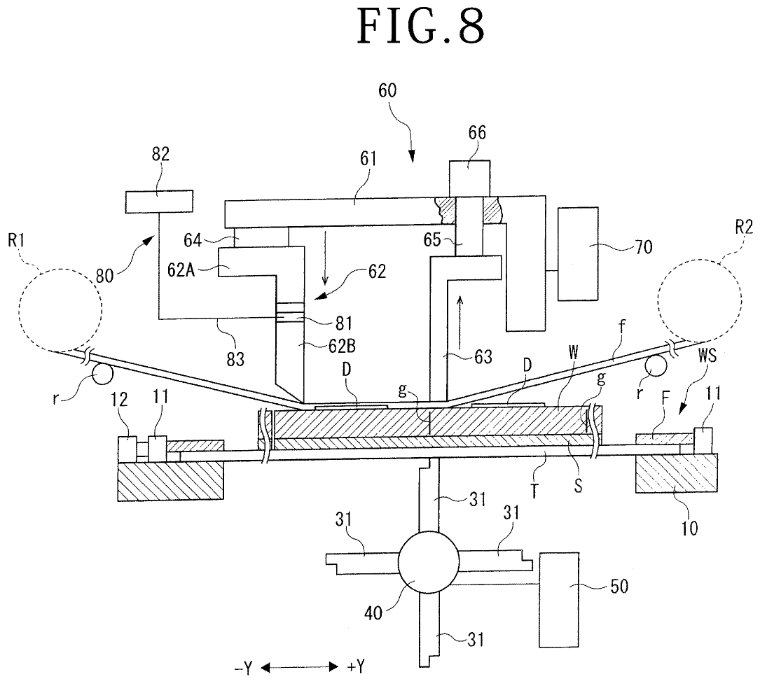

In the gripping step, as illustrated in FIG. 8, the lower bar raising and lowering mechanism 50 raises the lower bars 31 until the distal end of one of the lower bars 31 abuts against the lower surface of the wafer W with the sheet T interposed therebetween in alignment with one of the streets L1, i.e., one of the division initiating points g. The presser bar raising and lowering mechanism 70 lowers the slider 61 and the presser bar 62 and the upper bar 63 that are supported on the slider 61, until the upper bar 63 has its lower surface brought into abutment against the upper surface of the wafer W with the protective film f interposed therebetween in alignment with the one of the streets L1, i.e., the one of the division initiating points g and also until the knife edge of the lower end of the presser bar 62 abuts against the upper surface of the wafer W with the protective film f interposed therebetween at a position offset from the one of the division initiating points g in the −Y direction. Therefore, the wafer W has the upper and lower surfaces of its portion that is aligned with the one of the division initiating points g gripped by the upper bar 63 and the lower bar 31 that is abutting against the lower surface of the wafer W, with the protective film f and the sheet T interposed therebetween.

### 3) Dividing Step:

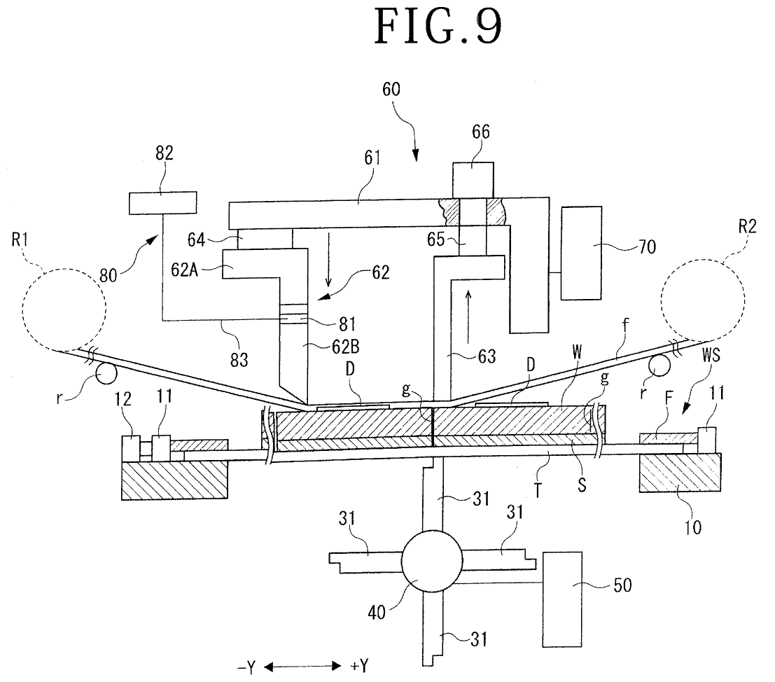

In the dividing step, as illustrated in FIG. 9, the ultrasonic vibration applying unit 80 applies ultrasonic vibrations to the presser bar 62 while the knife edge of the lower end of the presser bar 62 is pressing the upper surface of the wafer W with the protective film f interposed therebetween at the position offset from the one of the division initiating points g in the −Y direction. Specifically, the high-frequency power supply 82 of the ultrasonic vibration applying unit 80 is turned on to apply the high-frequency electric power via the power cord 83 to the ultrasonic vibrator 81, actuating, i.e., exciting, the ultrasonic vibrator 81 to vibrate the presser bar 62 ultrasonically. The wafer W is now reliably severed along the one of the division initiating points g due to brittle fracture caused by the vibrational energy propagated from the presser bar 62, i.e., due to its fatigue breakdown caused by repetitive stresses.

According to the present embodiment, as illustrated in FIG. 9, the upper surface of the portion of the wafer W that includes the division initiating points g where the wafer W is to be divided in the dividing step is covered with the protective film f. Therefore, the devices D are protected by the protective film f. Moreover, particles produced from the wafer W as it is divided by the presser bar 62 are prevented from being scattered around by the protective film f.

When the severance or division of the wafer W along the one of the streets L1 is finished, the holding step, the gripping step, and the dividing step are repeated on the wafer W along a next street L1, as with the first embodiment. When the division of the wafer W along all of the streets L1 is finished, the rotating mechanism, not depicted, rotates the holding table 10 and the wafer W, i.e., the frame unit WS, held thereon about its vertical central axis through an angle of 90°, and the holding step, the gripping step, and the dividing step are carried out on the wafer W along one of the streets L2 that extend perpendicularly to the streets L1. When the division of the wafer W along all of the streets L2 is finished, the wafer W has been divided into a plurality of chips. The present embodiment offers the same advantages as those of the first embodiment.

### [Second Invention]

Preferred embodiments of a second invention will be described in detail below with reference to the accompanying drawings.

### First Embodiment

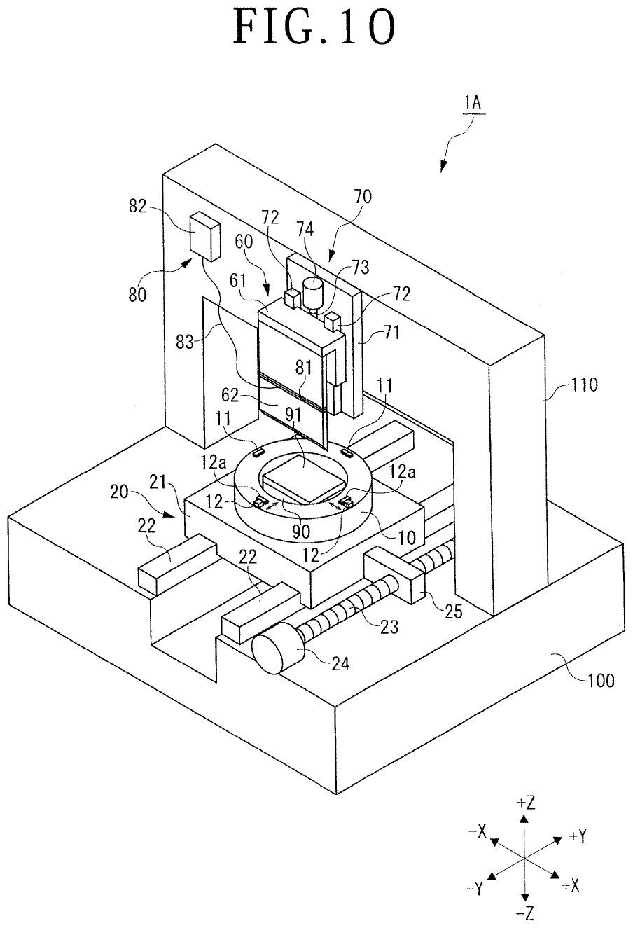

First, structural details of an apparatus 1A (see FIG. 10) for dividing a wafer according to a first embodiment of the second invention will be described below. The wafer dividing apparatus 1A illustrated in FIG. 10 has a basic structure that is the same as that of the wafer dividing apparatus 1 according to the first invention illustrated in FIG. 1. Those parts of the wafer dividing apparatus 1A that are identical to those of the wafer dividing apparatus 1 illustrated in FIG. 1 are denoted by identical reference symbols, and will be omitted from detailed description.

The wafer dividing apparatus 1A illustrated in FIG. 10 includes a support 90 shaped as a rectangular block disposed within the ring-shaped holding table 10. The support 90 has a flat upper surface to which there is attached an elastic member 91 shaped as a rectangular plate that is elastically deformable to allow the wafer W to be deformed when the wafer W is divided on the holding table 10. The presser bar mechanism 60 includes a presser bar 62 vertically mounted on and hanging downwardly from the slider 61 and a presser bar raising and lowering mechanism 70 mounted on the column 110 for raising and lowering the presser bar 62. The presser bar mechanism 60 is free of the upper bar 63. The other structural details of the presser bar mechanism 60 according to the present embodiment are identical to those of the presser bar mechanism 60 of the wafer dividing apparatus 1 according to the first invention illustrated in FIG. 1.

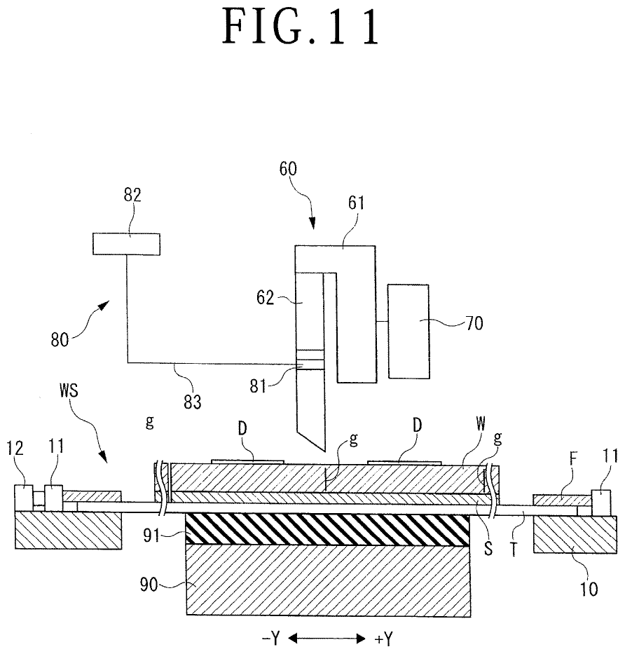

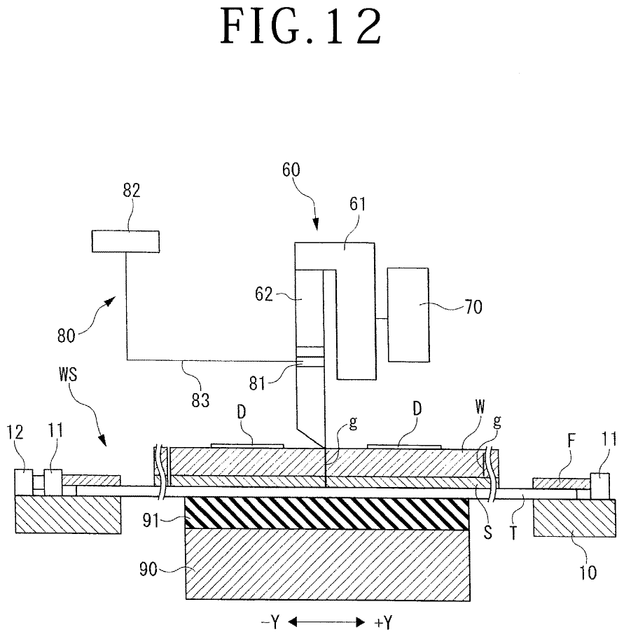

A method of dividing a wafer, also referred to as a “wafer dividing method,” according to the first embodiment of the second invention, which is carried out by the wafer dividing apparatus 1A, will be described below. The wafer dividing method refers to a method of dividing the wafer W to produce a plurality of chips therefrom by performing 1) a holding step and 2) a dividing step successively in the order named. 1) The holding step and 2) the dividing step will be described below with reference to FIGS. 11 and 12.

### 1) Holding Step:

The holding step is the same as the holding step of the wafer dividing method according to the first invention. As illustrated in FIG. 11, the frame unit WS is placed on the holding table 10, and the ring frame F of the frame unit WS has its outer circumferential edge held against the two fixed clamps 11. Then, the pressers 12a of the two movable clamps 12 are moved radially inwardly on the holding table 10, pressing the outer circumferential edge of the ring frame F against the two fixed clamps 11. The ring frame F and hence the frame unit WS are now held as securely positioned on the holding table 10.

When the ring frame F of the frame unit WS is held as positioned on the holding table 10, the lower surface of the wafer W is borne by and supported on the support 90 with the sheet T and the elastic member 91 interposed therebetween.

### 2) Dividing Step:

In the dividing step, as illustrated in FIG. 11, the ultrasonic vibration applying unit 80 applies ultrasonic vibrations to the presser bar 62 while the knife edge of the lower end of the presser bar 62 is pressing the upper surface of the wafer W at one of the streets L1, i.e., one of the division initiating points g. Specifically, the high-frequency power supply 82 of the ultrasonic vibration applying unit 80 is turned on to apply the high-frequency electric power via the power cord 83 to the ultrasonic vibrator 81, actuating, i.e., exciting, the ultrasonic vibrator 81 to vibrate the presser bar 62 ultrasonically. The wafer W is now reliably severed along the one of the division initiating points g due to brittle fracture caused by the vibrational energy propagated from the presser bar 62, i.e., due to its fatigue breakdown caused by repetitive stresses. In the dividing step, since the elastic member 91 is elastically deformed at the one of the dividing initiating points g in the wafer W, allowing the wafer W to be deformed, the wafer W is effectively severed along the one of the dividing initiating points g.

When the severance or division of the wafer W along the one of the streets L1 is finished, the horizontal moving mechanism 20 illustrated in FIG. 10 is actuated to move the holding table 10 and the wafer W, i.e., the frame unit WS, held thereon by a pitch, i.e., the distance between two adjacent streets L1, in an indexing direction along the Y-axis. Thereafter, the holding step and the dividing step are repeated on the wafer W along a next street L1. When the division of the wafer W along all of the streets L1 is finished, the rotating mechanism, not depicted, rotates the holding table 10 and the wafer W, i.e., the frame unit WS, held thereon about its vertical central axis through an angle of 90°, and the holding step and the dividing step are carried out on the wafer W along one of the streets L2 that extend perpendicularly to the streets L1. When the division of the wafer W along all of the streets L2 is finished, the wafer W has been divided into a plurality of chips.

With the wafer dividing method according to the first embodiment of the second invention, even the wafer W backed with the metal film S on its reverse side can reliably be divided along the division initiating points g within a short period of time without the need for strong forces that would otherwise be applied to the wafer W and without damage caused to the chips produced from the wafer W. Even if the wafer W is thicker, the wafer W can be divided along the division initiating points g reliably within a short period of time without the need for strong forces that would otherwise be applied to the wafer W and without causing damage to the chips produced from the wafer W.

### Second Embodiment

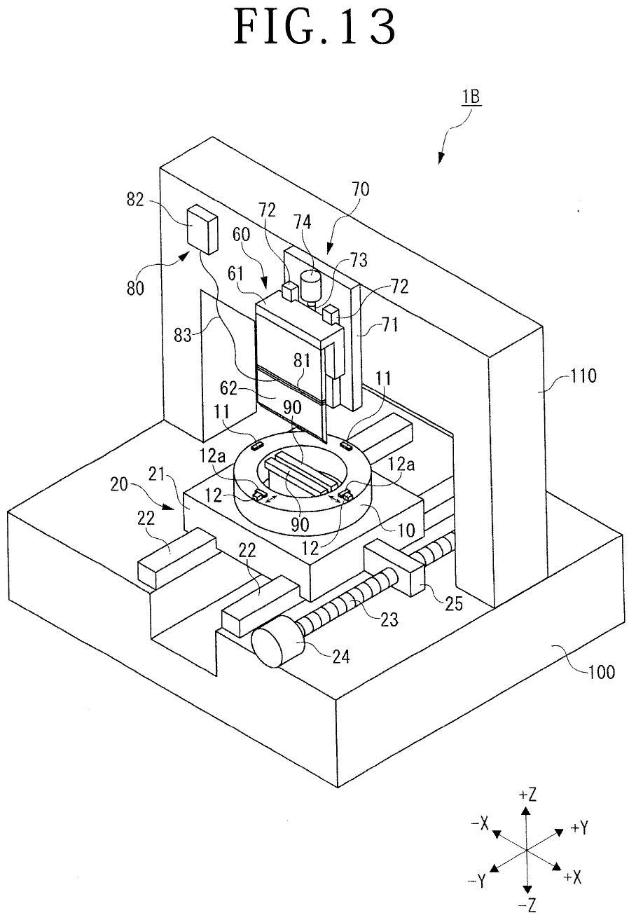

A second embodiment of the second invention will be described in detail below with reference to FIGS. 13 through 15.

FIG. 13 illustrates in perspective an apparatus 1B for dividing the wafer W according to the second embodiment of the second invention. The wafer dividing apparatus 1B illustrated in FIG. 13 has a basic structure that is the same as those of the wafer dividing apparatuses 1 and 1A illustrated respectively in FIGS. 1 and 10. Those parts of the wafer dividing apparatus 1B that are identical to those of the wafer dividing apparatuses 1 and 1A illustrated respectively in FIGS. 1 and 10 are denoted by identical reference symbols, and will be omitted from detailed description.

The wafer dividing apparatus 1B illustrated in FIG. 13 includes a pair of supports 90 each shaped as a rectangular block disposed within the ring-shaped holding table 10. The supports 90 are elongate along the X-axis and are spaced from each other along the Y-axis. The presser bar mechanism 60 includes a presser bar 62 vertically mounted on and extending downwardly from the slider 61 and a presser bar raising and lowering mechanism 70 mounted on the column 110 for raising and lowering the presser bar 62. The presser bar mechanism 60 is free of the upper bar 63. The other structural details of the presser bar mechanism 60 according to the present embodiment are identical to those of the presser bar mechanism 60 of the wafer dividing apparatus 1A according to the first embodiment illustrated in FIG. 10.

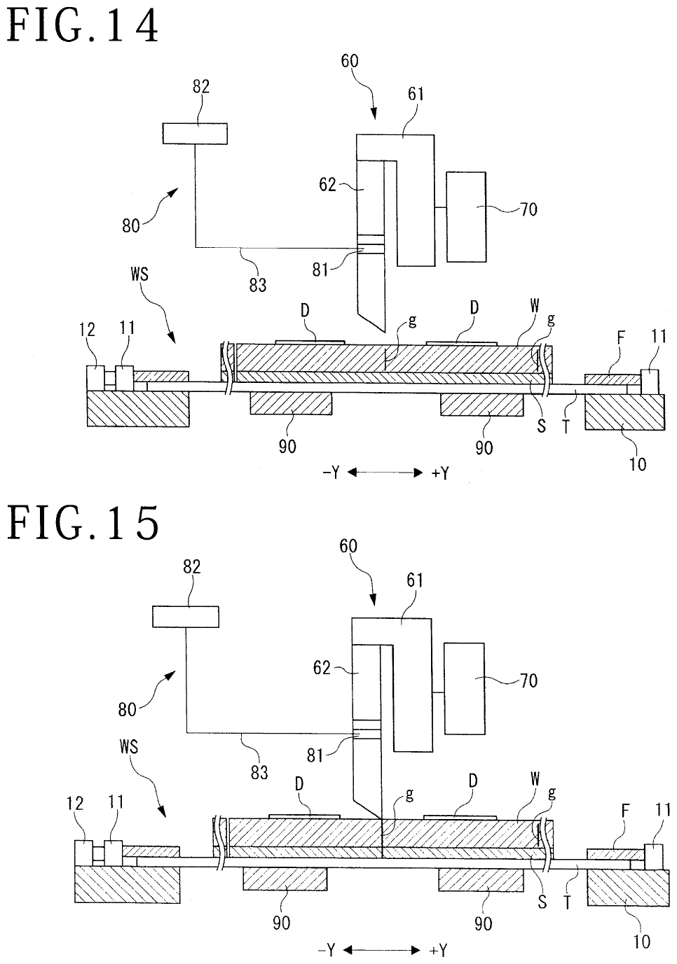

A method of dividing the wafer W according to the second embodiment of the second invention, which is carried out by the wafer dividing apparatus 1B illustrated in FIG. 13, will be described below. The wafer dividing method refers to a method of dividing the wafer W to produce a plurality of chips therefrom by performing 1) a holding step and 2) a dividing step successively in the order named. 1) The holding step and 2) the dividing step will be described below with reference to FIGS. 14 through 15.

### 1) Holding Step:

The holding step is the same as the holding step of the wafer dividing method according to the first invention. As illustrated in FIG. 14, the frame unit WS is placed on the holding table 10, and the ring frame F of the frame unit WS has its outer circumferential edge held against the two fixed clamps 11. Then, the pressers 12a of the two movable clamps 12 are moved radially inwardly on the holding table 10, pressing the outer circumferential edge of the ring frame F against the two fixed clamps 11. The ring frame F and hence the frame unit WS are now held as securely positioned on the holding table 10.

When the ring frame F of the frame unit WS is held as positioned on the holding table 10, the lower surface of the wafer W is borne by and supported on the two supports 90 with the sheet T interposed therebetween.

### 2) Dividing Step:

In the dividing step, as illustrated in FIG. 15, the ultrasonic vibration applying unit 80 applies ultrasonic vibrations to the presser bar 62 while the knife edge of the lower end of the presser bar 62 is pressing the upper surface of the wafer W at one of the streets L1, i.e., one of the division initiating points g. Specifically, the high-frequency power supply 82 of the ultrasonic vibration applying unit 80 is turned on to apply the high-frequency electric power via the power cord 83 to the ultrasonic vibrator 81, actuating, i.e., exciting, the ultrasonic vibrator 81 to vibrate the presser bar 62 ultrasonically. The wafer W is now reliably severed along the one of the division initiating points g due to brittle fracture caused by the vibrational energy propagated from the presser bar 62, i.e., due to its fatigue breakdown caused by repetitive stresses. In the dividing step, as the lower surface of the portion of the wafer W that includes the one of the division initiating points g in the wafer W is supported on the two supports 90 that are spaced from each other along the Y-axis, the wafer W is allowed to be deformed by the gap between the two supports 90 at the time the wafer W is divided along the one of the dividing initiating points g.

When the severance or division of the wafer W along the one of the streets L1 is finished, the horizontal moving mechanism 20 illustrated in FIG. 13 is actuated to move the holding table 10 and the wafer W, i.e., the frame unit WS, held thereon by a pitch, i.e., the distance between two adjacent streets L1, in an indexing direction along the Y-axis. Thereafter, the holding step and the dividing step are repeated on the wafer W along a next street L1. When the division of the wafer W along all of the streets L1 is finished, the rotating mechanism, not depicted, rotates the holding table 10 and the wafer W, i.e., the frame unit WS, held thereon about its vertical central axis through an angle of 90°, and the holding step and the dividing step are carried out on the wafer W along one of the streets L2 that extend perpendicularly to the streets L1. When the division of the wafer W along all of the streets L2 is finished, the wafer W has been divided into a plurality of chips.

With the wafer dividing method according to the second embodiment of the second invention, as with the first embodiment, even the wafer W backed with the metal film S on its reverse side can reliably be divided along the division initiating points g within a short period of time without the need for strong forces that would otherwise be applied to the wafer W and without damage caused to the chips produced from the wafer W. Even if the wafer W is thicker, the wafer W can be divided along the division initiating points g reliably within a short period of time without the need for strong forces that would otherwise be applied to the wafer W and without causing damage to the chips produced from the wafer W.

In the embodiments described above, the modified layers formed in the wafer W by the laser beam applied to the wafer W are used as the division initiating points g. However, the division initiating points g may be formed as grooves in the wafer W by blade dicing processing that forms cut grooves or kerfs in the wafer W with use of a cutting blade that cuts the wafer W along the streets, plasma dicing processing that forms grooves in the wafer W along the streets by performing plasma etching on the wafer W in a vacuum, or laser ablation processing that forms grooves in the wafer W along the streets by applying a laser beam to the face side of the wafer W.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of dividing a wafer along division initiating points formed in the wafer along a grid of streets established on a face side of the wafer, the method comprising:
a holding step of holding a ring frame that supports the wafer through a sheet affixed to the ring frame and a reverse side, opposite the face side, of the wafer, on a ring-shaped holding table;
a gripping step of gripping the wafer between a lower bar that abuts against a lower surface of the sheet along the streets on the wafer and an upper bar that abuts against an upper surface of the wafer along the streets thereon; and
a dividing step of severing the wafer along the division initiating points by pressing a presser bar extending parallel to the upper bar against the upper surface of the wafer at a position spaced from the upper bar while the presser bar is being ultrasonically vibrated.

2. A method of dividing a wafer along division initiating points formed in the wafer along a grid of streets established on a face side of the wafer, the method comprising:
a holding step of holding a ring frame that supports the wafer through a sheet affixed to the ring frame and a reverse side, opposite the face side, of the wafer, on a ring-shaped holding table; and
a dividing step of severing the wafer along the division initiating points by pressing a presser bar downwardly against an upper surface of the wafer along the streets with the sheet having a lower surface supported on a support while the presser bar is being ultrasonically vibrated.

3. An apparatus for dividing a wafer along division initiating points formed in the wafer along a grid of streets established on a face side of the wafer, the apparatus comprising:
a ring-shaped holding table for holding thereon a ring frame of a frame unit that includes the ring frame, the wafer, and a sheet affixed to the ring frame and the wafer, thereby supporting the wafer on the ring frame through the sheet;
a lower bar disposed within the holding table for linearly abutting against the sheet of the frame unit held on the holding table;
a lower bar raising and lowering mechanism for raising and lowering the lower bar;
an upper bar disposed in confronting relation to the lower bar for linearly abutting against an upper surface of the wafer of the frame unit held on the holding table;
an upper bar raising and lowering mechanism for raising and lowering the upper bar;
a presser bar disposed parallel to the upper bar for pressing the wafer of the frame unit held on the holding table; and
an ultrasonic vibrator attached to the presser bar for ultrasonically vibrating the presser bar.

4. An apparatus for dividing a wafer along division initiating points formed in the wafer along a grid of streets established on a face side of the wafer, the apparatus comprising:
a ring-shaped holding table for holding thereon a ring frame of a frame unit that includes the ring frame, the wafer, and a sheet affixed to the ring frame and the wafer, thereby supporting the wafer on the ring frame through the sheet;
a support disposed within the holding table for supporting a lower surface of the sheet of the frame unit held on the holding table;
a presser bar for pressing the wafer downwardly along the streets; and
an ultrasonic vibrator attached to the presser bar for ultrasonically vibrating the presser bar.
